(19) United States
(12) Patent Application Publication
(10) Pub. No.: US 2018/0376041 A1
(43) Pub. Date: Dec. 27, 2018

(54) IMAGE SENSOR MOUNTING BOARD AND IMAGING DEVICE

(71) Applicant: KYOCERA Corporation, Kyoto-shi, Kyoto (JP)

(72) Inventors: Kouji MIURA, Satsumasendai-shi (JP); Kanae HORIUCHI, Satsumasendai-shi (JP)

(73) Assignee: KYOCERA Corporation, Kyoto-shi, Kyoto (JP)

(21) Appl. No.: 16/062,859

(22) PCT Filed: Dec. 14, 2016
(86) PCT No.: PCT/JP2016/087264

§ 371 Date: Jun. 15, 2018

(30) Foreign Application Priority Data
Dec. 24, 2015 (JP) 2015-251697

(51) Int. Cl. H04N 5/225; H01L 27/146; H01L 23/00

(52) U.S. Cl. CPC H04N 5/2253; H01L 27/14618; H01L 24/48; H01L 24/49; H01L 2224/73265; H04N 5/2254; H01L 2224/49176; H01L 2224/48091; H01L 2224/48157; H01L 24/73

(57) ABSTRACT

An image sensor mounting board includes an inorganic substrate, a wiring board, and a bond. The inorganic substrate includes an image sensor mount in a central area of its upper surface, in which an image sensor is mountable. The inorganic substrate includes a protrusion protruding upward in a peripheral area surrounding the image sensor mount. The wiring board is a frame arranged on the upper surface of the inorganic substrate to surround the image sensor mount and have a lower surface partially in contact with the protrusion. The wiring board includes a lens mount on its upper surface. The bond is located between the inorganic substrate and the wiring board.

### FIELD

The present invention relates to a wiring board on which an image sensor, such as a charge-coupled device (CCD) or a complementary metal oxide semiconductor (CMOS) device, is mounted, and to an imaging device.

### BACKGROUND

An image sensor mounting board including an inorganic substrate and a wiring board is known, as described in Japanese Unexamined Patent Application Publication No. 2008-187554. The inorganic substrate and the wiring board are usually joined together with a bond. An image sensor and a lens holder are then mounted on this image sensor mounting board to complete an imaging device.

However, the bond for joining the wiring board and the inorganic substrate can easily have varying thicknesses. The wiring board and the inorganic substrate may not be easily aligned parallel to each other accurately. This may prevent the lens holder mounted on the wiring board from being aligned parallel to the inorganic substrate.

### BRIEF SUMMARY

An image sensor mounting board according to one aspect of the present invention includes an inorganic substrate, a wiring board, and a bond. The inorganic substrate includes an image sensor mount in a central area of an upper surface of the inorganic substrate, in which an image sensor is mountable. The inorganic substrate includes a protrusion protruding upward in a peripheral area surrounding the image sensor mount. The wiring board is a frame arranged on an upper surface of the inorganic substrate to surround the image sensor mount and have a lower surface partially in contact with the protrusion. The wiring board includes a lens mount on its upper surface. The bond is located between the inorganic substrate and the wiring board.

An imaging device according to another aspect of the present invention includes an image sensor mounted on an image sensor mount included in an inorganic substrate in an image sensor mounting board, and a lens holder fixed on the lens mount included in the wiring board.

### BRIEF DESCRIPTION OF DRAWINGS

FIG. 1A is an external top view of an image sensor mounting board and an imaging device according to a first embodiment of the present invention, and FIG. 1B is a cross-sectional view taken along line A-A in FIG. 1A.

FIG. 2A is an external top view of an imaging device according to a modification of the first embodiment of the present invention, and FIG. 2B is a cross-sectional view taken along line B-B in FIG. 2A.

FIG. 3A is an external bottom view of an image sensor mounting board according to a modification of the first embodiment of the present invention.

FIGS. 4A and 4B are external bottom views of image sensor mounting boards according to modifications of the first embodiment of the present invention.

FIG. 5A is an external top view of an image sensor mounting board and an imaging device according to a second embodiment of the present invention, and FIG. 5B is a cross-sectional view taken along line C-C in FIG. 5A.

FIG. 6A is an external top view of an image sensor mounting board and an imaging device according to a third embodiment of the present invention, and FIG. 6B is a cross-sectional view taken along line D-D in FIG. 6A.

FIG. 7A is an external top view of an image sensor mounting board and an imaging device according to a fourth embodiment of the present invention, and FIG. 7B is a cross-sectional view taken along line E-E in FIG. 7A.

FIGS. 8A and 8B are external bottom views of image sensor mounting boards according to modifications of the fourth embodiment of the present invention.

### DETAILED DESCRIPTION

Embodiments of the present invention will now be described by way of example with reference to the drawings. In the embodiments described below, an imaging device includes an image sensor mounted on an image sensor mounting board with a lid bonded to the upper surface of the image sensor mounting board. Although the image sensor mounting board and the imaging device may be arranged to have any of their faces upward or downward, they are herein defined using the orthogonal xyz coordinate system with the positive z direction upward for ease of explanation.

### First Embodiment

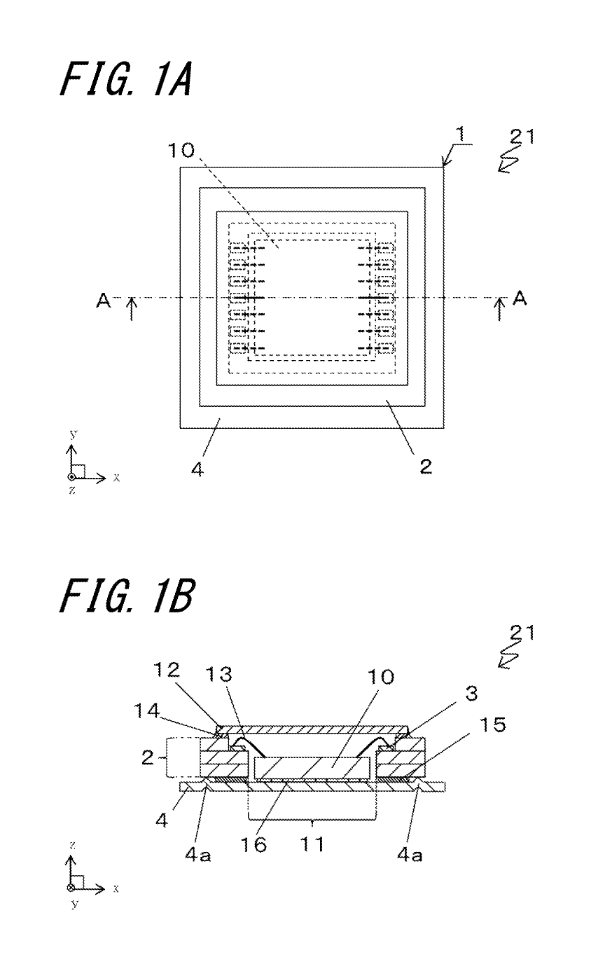

An imaging device 21 and an image sensor mounting board 1 according to a first embodiment of the present invention will be described with reference to FIGS. 1A to 4B. The imaging device 21 according to the present embodiment includes the image sensor mounting board 1, an image sensor 10, and a lens holder 19, although the lens holder 19 is not shown in FIGS. 1A and 1B.

The image sensor mounting board 1 includes an inorganic substrate 4, a wiring board 2, and a bond 15. The inorganic substrate 4 includes, in the central area of its upper surface, an image sensor mount 11 on which the image sensor 10 is mountable. The inorganic substrate 4 includes a protrusion 4a protruding upward in a peripheral area surrounding the image sensor mount 11. The wiring board 2 is a frame arranged on the upper surface of the inorganic substrate 4 to surround the image sensor mount 11 and having its lower surface partially in contact with the protrusion 4a. The wiring board 2 includes a lens mount on its upper surface. The bond 15 is arranged between the inorganic substrate 4 and the wiring board 2.

The image sensor mounting board 1 includes the inorganic substrate 4 including, on its upper surface, the image sensor mount 11 on which the image sensor 10 is mountable.

The inorganic substrate 4 is formed from, for example, a material with high thermal conductivity. Examples of the material for the inorganic substrate 4 include sintered aluminum nitride, sintered silicon nitride, and silicon (Si). Other materials may also be used. When the inorganic substrate 4 is formed from, for example, sintered aluminum nitride or sintered silicon nitride, the inorganic substrate 4 may be a laminate of multiple insulating layers. The inorganic substrate 4 may further have a conductive layer on the surface of the laminate of multiple insulating layers.

The inorganic substrate 4 may also be formed from a metal including stainless steel (SUS), an Fe—Ni—Co alloy, alloy 42, copper (Cu), Kovar, and a copper alloy. Other metal materials may also be used. For example, when the wiring board 2 is formed from sintered aluminum oxide with a coefficient of thermal expansion of about 5×10⁻⁶/° C. to 10×10⁻⁶/° C., the inorganic substrate 4 may be formed from stainless steel (SUS304) with a coefficient of thermal expansion of about 10×10⁻⁶/° C. In this case, the wiring board 2 undergoes thermal contraction and expansion with small differences from the inorganic substrate 4. This reduces deformation of the electronic component mount 11. This then reduces optical axis misalignment between the image sensor 10 and the lens, thus producing clear images. The inorganic substrate 4 formed from a metal material, which is non-magnetic, is prevented from being magnetized, and is prevented from interfering with the operation of external devices, such as a lens drive.

The image sensor mounting board 1, which is arranged on the upper surface of the inorganic substrate 4, includes a wiring board as a frame surrounding the image sensor mount 11. The wiring board includes, on its upper surface, the wiring board 2 including the lens mount.

The wiring board 2 includes an insulating layer, and may include image sensor connection pads 3 on its upper surface. The wiring board 2 may include, on its lower surface, multiple electrodes (not shown) for connection to external circuits or to the inorganic substrate 4. The insulating layers included in the wiring board 2 is formed from, for example, an electrical insulating ceramic material or a resin (plastics).

Examples of the electrical insulating ceramic material used for the insulating layer forming the wiring board 2 include sintered aluminum oxide, sintered mullite, sintered silicon carbide, sintered aluminum nitride, sintered silicon nitride, and sintered glass ceramic. Other materials may also be used.

Examples of the resin used for the insulating layer forming the wiring board 2 include an epoxy resin, a polyimide resin, an acryl resin, a phenolic resin, and a fluorine-based resin. Examples of the fluorine-based resin include a polyester resin and a polytetrafluoroethylene resin. Other materials may also be used.

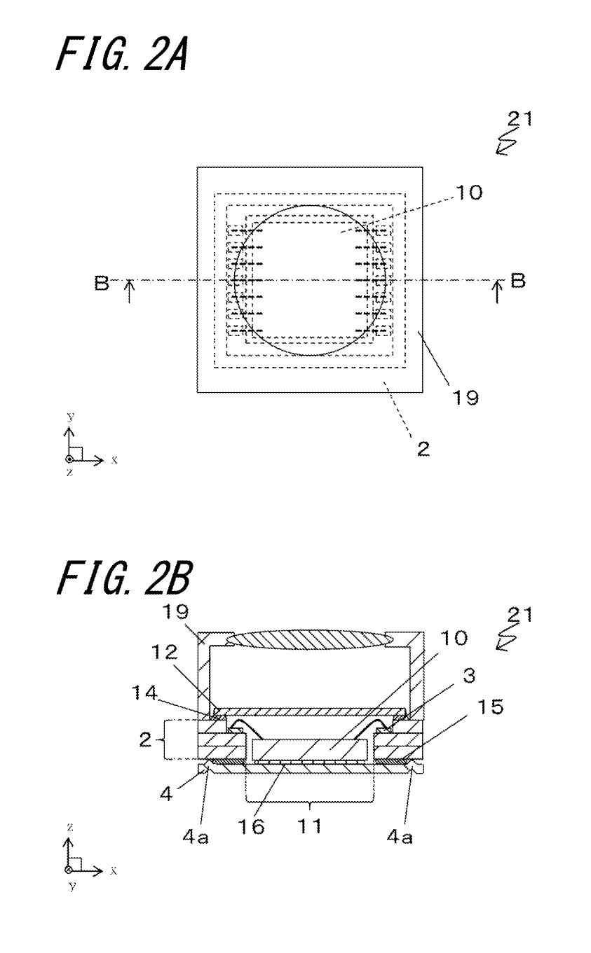

The insulating layer forming the wiring board 2 may include multiple insulating layers formed from the above material stacked on one another. The insulating layers forming the wiring board 2 may be three insulating layers as shown in FIGS. 1B and 2B, a single, two, four, or more insulating layers. As in the examples shown in FIGS. 1A to 2B, the insulating layers forming the wiring board 2 may have openings with different sizes. The openings may define a step, on which multiple image sensor connection pads 3 may be placed.

The wiring board 2 may have electrodes for connection to external circuits on its upper surface, side surface, or lower surface. The electrodes for connection to external circuits electrically connect the wiring board 2 or the imaging device 21 to external circuit boards.

The wiring board 2 may include inner wires between the insulating layers, and feedthrough conductors that vertically connect the inner wires to one another. The inner wires or the feedthrough conductors may be uncovered on the surface of the wiring board 2. The inner wires or the feedthrough conductors may electrically connect the electrodes for connection to external circuits and the image sensor connection pads 3.

When the wiring board 2 is formed from an electrical insulating ceramic material, the image sensor connection pads 3, the electrodes for connection to external circuits, the inner wires, and the feedthrough conductors are formed from tungsten (W), molybdenum (Mo), manganese (Mn), silver (Ag), or copper (Cu), or an alloy containing one or more of these metals. When the wiring board 2 is formed from a resin, the image sensor connection pads 3, the electrodes for connection to external circuits, the inner wires, and the feedthrough conductors are formed from copper (Cu), gold, (Au), aluminum (Al), nickel, (Ni), molybdenum (Mo), or titanium (Ti), or an alloy containing one or more of these metals.

The image sensor connection pads 3, the electrodes for connection to external circuits, the inner wires, and the feedthrough conductors may be plated. The plating layer protects the uncovered surfaces of the image sensor connection pads 3, the electrodes for connection to external circuits, the inner wires, and the feedthrough conductors against oxidation. The plating layer also improves the electrical connection between the image sensor connection pads 3 and the image sensor 10 with a connection 13, such as wire bonding. The plating layer may be, for example, a Ni plating layer with a thickness of 0.5 to 10 μm, or this Ni plating layer may further be coated with a gold (Au) plating layer with a thickness of 0.5 to 3 μm.

The image sensor mounting board 1 includes the bond 15 between the inorganic substrate 4 and the wiring board 2. The vertical thickness of the bond 15 is the height of the protrusion 4a protruding upward from the upper surface of the inorganic substrate 4, and is, for example, 10 to 200 μm.

Examples of the material used for the bond 15 include a thermosetting resin and a brazing material. Examples of the thermosetting resin used for the bond 15 include a bisphenol A liquid epoxy resin. Examples of the brazing material used for the bond 15 include solder, lead, and glass.

The bond 15 may be conductive or non-conductive. Examples of the conductive bond 15 include silver epoxy, solder, an anisotropic conductive resin (anisotropic conductive paste or ACP), and an anisotropic conductive film (ACF). The conductive bond 15 may electrically connect the wiring board 2 to the inorganic substrate 4. For example, the wiring board 2 is electrically connected to the inorganic substrate 4 with the same potential as a ground electrode. This allows the inorganic substrate 4 to function as a shield for protecting the image sensor 10 from external noise. Examples of the non-conductive bond 15 include a thermosetting resin.

The inorganic substrate 4 includes the protrusions 4a protruding upward in the peripheral area surrounding the image sensor mount 11. Each protrusion 4a is in contact with a part of the lower surface of the wiring board 2.

The imaging device 21 typically tends to have a larger number of pixels. In response to this, the image sensor 10 mounted on the inorganic substrate 4 and the lens holder 19 mounted on the wiring board 2 are to be aligned parallel to each other with high accuracy. However, the bond 15 for joining the wiring board 2 and the inorganic substrate 4 can easily have varying thicknesses. This may prevent accurate parallel alignment between the wiring board 2 and the inorganic substrate 4. This may thus prevent the lens holder 19 mounted on the wiring board 2 and the inorganic substrate 4 from easily being accurately arranged in parallel, thus causing image quality deterioration. In response to this, forming the protrusions 4a surrounding the image sensor mount 11 on the inorganic substrate 4 and each in contact with a part of the lower surface of the wiring board 2 allows the wiring board 2 and the inorganic substrate 4 to be uniformly apart. This reduces the inclination between the wiring board 2 and the inorganic substrate 4 independently of any variations in the thickness of the bond 15. The wiring board 2 and the inorganic substrate 4 may thus be aligned parallel to each other more accurately. In other words, this structure reduces the inclination between the image sensor 10 mounted on the inorganic substrate 4 and the lens holder 19 mounted on the upper surface of the wiring board 2.

The protrusions 4a are formed on the upper surface of the inorganic substrate 4. The lower surface of the inorganic substrate 4 that overlaps the protrusions 4a as viewed through from above may be flat or may have recesses at positions that overlap the protrusions 4a. Each recess overlapping the protrusion 4a formed on the lower surface of the inorganic substrate 4 can be used as an index to determine the orientation when the imaging device 21 is viewed from below. The protrusions 4a are visible as viewed from below, and thus may also be used as alignment marks in the process of mounting the inorganic substrate 4.

Each protrusion 4a may be formed on the upper surface of the inorganic substrate 4 by bonding the same material as or a material different from the material for the inorganic substrate 4 or by raising a part of the inorganic substrate 4 with a method described later.

In some embodiments, multiple protrusions 4a may be formed at horizontally symmetric positions on the image sensor mount 11 as viewed from above. This structure allows the inorganic substrate 4 to be mounted in a horizontally well-balanced manner, and allows the lens in the lens holder 19 and the image sensor 10 mounted on the upper surface of the inorganic substrate 4 to be aligned parallel to each other more accurately.

As in the examples shown in FIGS. 1A and 1B, the inorganic substrate 4 may have its outer edge located outward from the outer edge of the wiring board 2 as viewed from above. When having its outer edge located outward from the outer edge of the wiring board 2 as viewed from above, the inorganic substrate 4 can easily receive impact from, for example, being dropped, thus reducing impact applied onto the wiring board 2.

As shown in FIGS. 2A and 2B, the inorganic substrate 4 may have its outer edge either at the same position as or inward from the outer edge of the wiring board 2 as viewed from above. When the inorganic substrate 4 has its outer edge at the same position as or inward from the outer edge of the wiring board 2 as viewed from above, the imaging device 21 may be downsized. Additionally, when the imaging device 21 is connected to external modules, the inorganic substrate 4 has its edge that is less likely to damage the wiring or other parts.

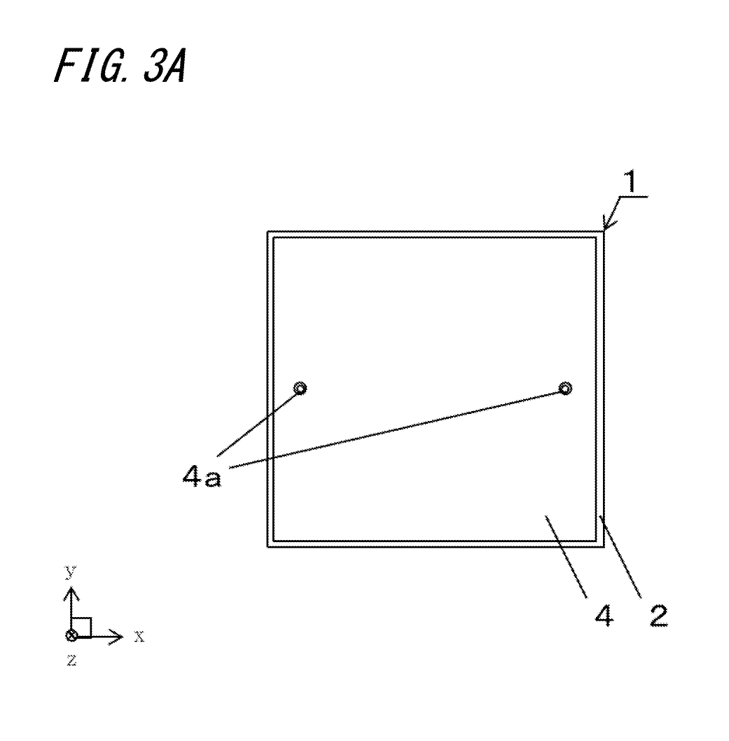

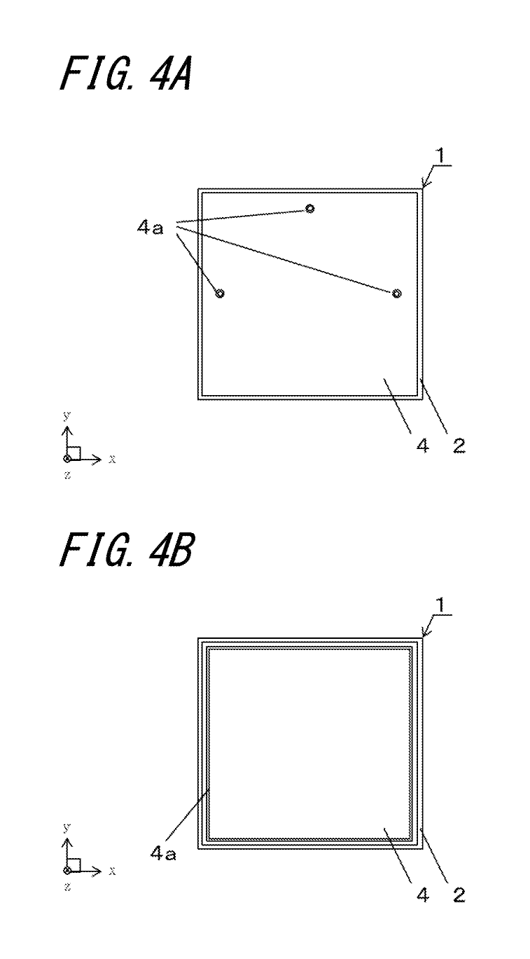

FIGS. 3A to 4B are bottom views of the imaging device 21 according to the present embodiment.

As in the example shown in FIG. 3A, multiple protrusions 4a are formed on the upper surface of the inorganic substrate 4, or may be formed at least on both sides of the image sensor mount 11. This structure may reduce the inclination between the inorganic substrate 4 and the wiring board 2 when the wiring board 2 is off-centered or when the wiring board 2 and the inorganic substrate 4 are joined together each under different stress applied from the upper surface. The inorganic substrate 4 and the wiring board 2 may thus remain aligned parallel to each other more accurately than when the protrusion 4a is formed at one position or across the corners of the image sensor 10. As in the example shown in FIG. 4A, multiple protrusions 4a are formed on the upper surface of the inorganic substrate 4 to have each protrusion 4a located near one of the three sides of the image sensor 10. This structure may further reduce the inclination between the inorganic substrate 4 and the wiring board 2 when the wiring board 2 is off-centered or when the wiring board 2 and the inorganic substrate 4 are joined together each under different stress applied from the upper surface. The inorganic substrate 4 and the wiring board 2 may thus remain aligned parallel to each other more accurately.

As in the example shown in FIG. 4B, the protrusion 4a may be a frame surrounding the image sensor mount 11. In this structure, the inorganic substrate 4 and the wiring board 2 remain aligned parallel to each other more accurately.

FIGS. 2A and 2B show the imaging device 21 with the lens holder 19.

The imaging device 21 includes the image sensor mounting board 1, the image sensor 10, and the lens holder 19. The image sensor 10 is mounted on the image sensor mount 11 included in the inorganic substrate 4 included in the image sensor mounting board 1. The lens holder 19 is fixed on the lens mount included in the wiring board 2.

The image sensor 10 is mounted on the image sensor mount 11 included in the inorganic substrate 4 in the image sensor mounting board 1. The image sensor 10 is, for example, a charge-coupled device (CCD) or a complementary metal oxide semiconductor (CMOS) device. The image sensor 10 may be arranged on the upper surface of the inorganic substrate 4 with an adhesive 16. The adhesive 16 is, for example, silver epoxy or a thermosetting resin.

The imaging device 21 may include a lid 12 on the upper surface of the wiring board 2 for sealing. The lid 12 is, for example, a flat plate. The lid 12 is a highly transparent member, such as glass. The lid 12 is attached to the upper surface of the wiring board 2 with a bonding member 14, such as a thermosetting resin or a brazing material formed from, for example, glass with a low melting point and a metal component.

The lens holder 19 is fixed on the lens mount included in the wiring board 2.

As in the examples shown in FIGS. 2A and 2B, the imaging device 21 includes the lens holder 19 to aid imaging. The lens holder 19 also improves hermetical sealing and prevents the image sensor mounting board 1 from directly receiving external stress.

The lens holder 19 is a housing formed from, for example, a resin to which one or more lenses formed from, for example, a resin, liquid, glass, or quartz are bonded. The lens holder 19 may include, for example, a drive for vertically or horizontally driving the lens, and may be electrically connected to the wiring board 2. As described above, when the lens holder 19 is mounted on the image sensor mounting board 1 having a small inclination between the wiring board 2 and the inorganic substrate 4 as in the embodiment of the present invention, the inclination between the lens placed on the lens holder 19 and the image sensor 10 may be reduced. This reduces image quality deterioration.

The lens holder 19 may have an opening in at least one of the four sides as viewed from above (not shown in the example in FIGS. 2A and 2B). Through the opening in the lens holder 19, an external circuit may be placed for electrical connection to the wiring board 2. After the external circuit is electrically connected to the wiring board 2, the opening in the lens holder 19 may be sealed with a sealant, such as a resin, to hermetically seal the inside of the imaging device 21.

The imaging device 21 may have the protrusions 4a and the feet of the lens holder 19 at positions overlapping each other as viewed through from above. This structure allows the lens of the lens holder 19 and the image sensor 10 mounted on the upper surface of the inorganic substrate 4 to be aligned parallel to each other more accurately.

An example method for manufacturing the image sensor mounting board 1 and the imaging device 21 according to the present embodiment will now be described. The example manufacturing method described below uses a multi-piece wiring substrate to be cut into the wiring boards 2.

(1) A ceramic green sheet that is to be the wiring board 2 is prepared first. To obtain, for example, the wiring board 2 formed from sintered aluminum oxide (Al₂O₃), powders, such as silica (SiO₂), magnesia (MgO), and calcium oxide (CaO), are added as a sintering aid to Al₂O₃ powder, and an appropriate binder, an appropriate solvent, and an appropriate plasticizer are added to the powder mixture, which is then kneaded to form slurry. The slurry is then shaped into a sheet using a known method such as a doctor blade or calendaring to obtain a ceramic green sheet for a multi-piece substrate.

The wiring board 2 formed from, for example, a resin may be molded using a mold having a predetermined shape by transfer molding or injection molding.

The wiring board 2 may be formed from a glass epoxy resin, which is a base glass fiber impregnated with a resin. In this case, the base glass fiber is impregnated with a precursor of an epoxy resin. The epoxy resin precursor is then cured by heat at a predetermined temperature to form the wiring board 2.

(2) A metal paste is then applied or placed, by screen printing or other techniques, into the areas to be the image sensor connection pads 3, the electrodes for connection to external circuits, the inner wires, and the feedthrough conductors in the ceramic green sheet obtained through the above process (1).

This metal paste is prepared by adding an appropriate solvent or an appropriate binder to the metal powder containing the above described metal material and then kneading the mixture to have an appropriate viscosity. The metal paste may contain glass or ceramic to increase the strength of bonding with the wiring board 2.

(3) The above green sheet is then processed using, for example, a mold. An opening is formed in the center of the green sheet, which is to be the wiring board 2.

(4) The ceramic green sheets to be the insulating layers are stacked and pressed to prepare a ceramic green sheet laminate to be the wiring board 2. In this process, a through-hole may be formed in each green sheet to be an insulating layer, and the green sheets are then stacked and pressed to form a ceramic green sheet laminate, which is to be the wiring board 2.

(5) The ceramic green sheet laminate is then fired at about 1,500 to 1,800° C. to obtain a multi-piece wiring substrate including an array of wiring boards 2. In this process, the metal paste described above is fired together with the ceramic green sheet to be the wiring board 2 to form the image sensor connection pads 3, the electrodes for connection to external circuits, the inner wires, and the feedthrough conductors.

(6) The multi-piece wiring substrate resulting from the firing process is then cut into multiple wiring boards 2. In this cutting process, separation grooves may be formed along the outer edge of each of the wiring boards 2, and the multi-piece wiring substrate may be split along the separation grooves into the multiple wiring boards 2. In other embodiments, the multi-piece wiring substrate may be cut along the outer edge of each of the wiring boards 2 by, for example, slicing. The separation grooves may be formed to have a depth smaller than the thickness of the multi-piece wiring substrate using a slicer after the firing process. In still other embodiments, the separation grooves may be formed by pressing a cutter blade onto the ceramic green sheet laminate that is to be the multi-piece wiring substrate or by cutting the ceramic green sheet laminate to a depth smaller than its thickness with a slicer.

(7) The inorganic substrate 4 to be bonded to the lower surface of the wiring board 2 is then prepared. The inorganic substrate 4 formed from a metal material is formed by, for example, punching a metal plate using a known stamping mold or etching a metal plate. The inorganic substrate 4 formed from a different material may be formed similarly by, for example, punching suitable for the material. The inorganic substrate 4 formed from a metal material, such as an Fe—Ni—Co alloy, alloy 42, Cu, or a copper alloy, may be coated with a nickel plating layer and a gold plating layer. The plating layers may effectively reduce oxidation and corrosion of the surface of the inorganic substrate 4.

The inorganic substrate 4 formed from electrical insulating ceramics may also be coated with a nickel plating layer and a gold plating layer when the substrate 4 has conductive patterns printed on its surface. The plating layer may effectively reduce oxidation and corrosion of the surface of the inorganic substrate 4.

In this process, the protrusion 4a may be formed on the upper surface of the inorganic substrate 4 by pressing an area to be the protrusion 4a using, for example, a mold on the lower surface of the inorganic substrate 4. The protrusion 4a may also be formed by bonding a separate material to be the protrusion 4a to the upper surface of the inorganic substrate 4 with, for example, a brazing material. The protrusion 4a protrudes upward from the upper surface of the inorganic substrate 4 by, for example, 5 to 100 μm. In some embodiments, the protrusion 4a may protrude upward from the upper surface of the inorganic substrate 4 by 10 to 200 μm. Multiple protrusions 4a may have a difference of 50 μm or lower between them in the vertical direction. The protrusion 4a may be circular as viewed from above and have a diameter of 5 to 100 μm, or may be a frame or a rectangle with a width of 5 to 200 μm.

(8) The wiring board 2 is then bonded to the inorganic substrate 4 with the bond 15. The bond 15, which is a thermosetting resin (adhesive) paste, is applied to either or both the bonding surfaces of the wiring board 2 and the inorganic substrate 4 by screen printing or dispensing. After the thermosetting resin is dried, the wiring board 2 and the inorganic substrate 4 remaining stacked are then passed through a furnace, such as an oven or an atmosphere furnace having a tunnel structure, to pressurize and heat the stack. The wiring board 2 and the inorganic substrate 4 are firmly bonded with the thermoset bond.

The bond 15 is prepared by adding a filler containing, for example, spherical silicon oxide particles, a curing agent mainly containing acid anhydrides such as tetrahydromethylphthalic anhydride, and a colorant containing carbon powders to a base agent containing, for example, a bisphenol A liquid epoxy resin, a bisphenol F liquid epoxy resin, or a phenolic novolac liquid epoxy resin. The resultant mixture is stirred or kneaded into a paste using a centrifugal stirrer.

The bond 15 may also be prepared by adding a curing agent such as imidazole, amine, phosphorous, hydrazine, imidazole adduct, amine adduct, cationic polymerization, or dicyandiamide to an epoxy resin such as a bisphenol A epoxy resin, a modified bisphenol A epoxy resin, a bisphenol F epoxy resin, a phenolic novolac epoxy resin, a cresol novolac epoxy resin, a special novolac epoxy resin, a phenol derivative epoxy resin, or an epoxy resin with a bisphenol skeleton.

(9) The image sensor 10 is then mounted on the image sensor mount 11 included in the inorganic substrate 4. The image sensor 10 is electrically bonded to the wiring board 2 by, for example, wire bonding. In some embodiments, the electronic component 10 may be fixed to the inorganic substrate 4 with an adhesive 16 or another bond applied to the electronic component 10 or to the inorganic substrate 4. After the image sensor 10 is mounted on the image sensor mount included in the inorganic substrate 4, the lid 12 may be bonded to the structure with a bond.

(10) The lens holder 19 is then mounted on the upper surface of the wiring board 2.

In this process, electrodes placed on the upper surface of the wiring board 2 and the lens holder 19 may be bonded with a conductive bond for electrical conductivity. In some embodiments, the lens holder 19 may be bonded with a non-conductive bond.

The wiring board 2 and the inorganic substrate 4 are combined in this manner to complete the electronic device 21 through the processes (1) to (10). The processes (1) to (10) above may be performed in any order.

### Second Embodiment

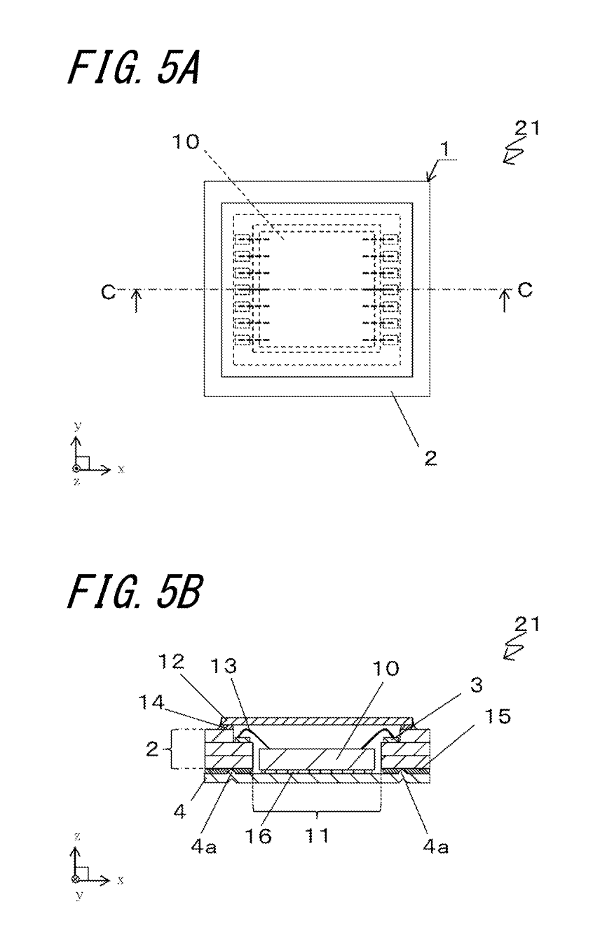

An image sensor mounting board 1 and an imaging device 21 according to a second embodiment of the present invention will now be described with reference to FIGS. 5A and 5B. The image sensor mounting board 1 and the imaging device 21 according to the present embodiment differ from the image sensor mounting board 1 and the imaging device 21 according to the first embodiment in that the protrusions 4a are surrounded by the bond 15 in a cross-sectional view. Although the imaging device 21 according to the present embodiment includes the image sensor mounting board 1, an image sensor 10, and a lens holder 19, the lens holder 19 is not shown in FIGS. 5A and 5B.

In the present embodiment shown in FIGS. 5A and 5B, the protrusions 4a formed on the upper surface of the inorganic substrate 4 are surrounded by the bond 15 in a cross-sectional view. When, for example, each protrusion 4a is formed by bonding a separate material on the upper surface of the inorganic substrate 4, each protrusion 4a surrounded by the bond 15 is prevented from being separated from the inorganic substrate 4. This structure also allows, for example, dust to be trapped between the protrusion 4a and the wiring board 2.

In the examples shown in FIGS. 5A and 5B, the image sensor 10 and the wiring board 2 are electrically bonded with a connection 13 (wire bonding), and the protrusions 4a are located near the end of the connection 13 as viewed from above. Connecting the connection 13 typically involves strong stress applied partially onto the wiring board 2. Such stress may cause cracks on the wiring board 2, or may deform the wiring board 2 to have an inclined upper surface. Each protrusion 4a located near the connection 13 as viewed from above can support the wiring board 2 on the lower surface. This reduces cracks in the wiring board 2 under stress applied when the connection 13 is connected. The wiring board 2 is supported to reduce deformation, and thus is less likely to have an inclined upper surface. This allows the lens holder 19 on the upper surface of the wiring board 2 to be aligned parallel to the image sensor 10 more accurately.

### Third Embodiment

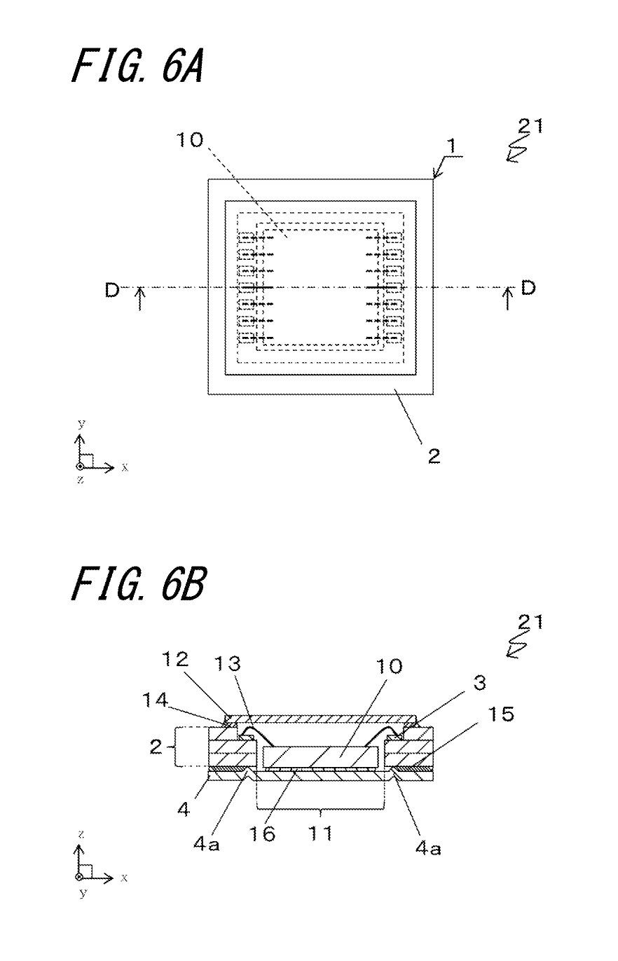

An image sensor mounting board 1 and an imaging device 21 according to a third embodiment of the present invention will now be described with reference to FIGS. 6A and 6B. The image sensor mounting board 1 and the imaging device 21 according to the present embodiment differ from the image sensor mounting board 1 and the imaging device 21 according to the first embodiment in that the protrusions 4a are formed around the image sensor mount 11 in a cross-sectional view. Although the imaging device 21 according to the present embodiment includes the image sensor mounting board 1, an image sensor 10, and a lens holder 19, the lens holder 19 is not shown in FIGS. 6A and 6B.

In the present embodiment shown in FIGS. 6A and 6B, the protrusions 4a on the inorganic substrate 4 are located around the image sensor mount 11 as viewed from above. This structure allows each protrusion 4a to serve as a barrier for blocking the bond 15 from flowing over the image sensor mount 11 when, for example, varying amounts of bond 15 are applied in the process of applying the bond 15, and the bond 15 is pressed toward the image sensor mount 11 in the bonding process. This prevents the image sensor 10 from failing to be mounted or from being mounted in a tilted manner due to the overflowing bond 15. Additionally, when the protrusion 4a extends continuously and surrounds the image sensor mount 11 or multiple protrusions 4a are formed with small spaces between them, the bond 15 may be prevented from flowing over the image sensor mount 11.

The structure according to the present embodiment may reduce the distance between the protrusions 4a facing each other. The image sensor mount 11 included in the inorganic substrate 4 may typically warp in the process of mounting the image sensor 10 or in the heating process. The facing protrusions 4a arranged at a reduced distance between them as in the present embodiment can reduce the degree of warping in the image sensor mount 11 between the facing protrusions 4a.

### Fourth Embodiment

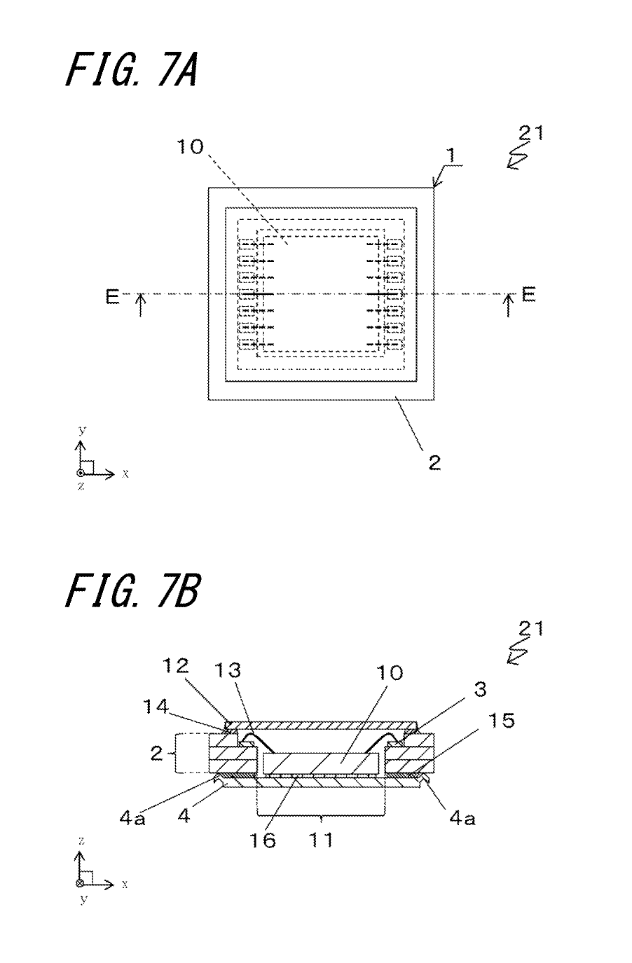

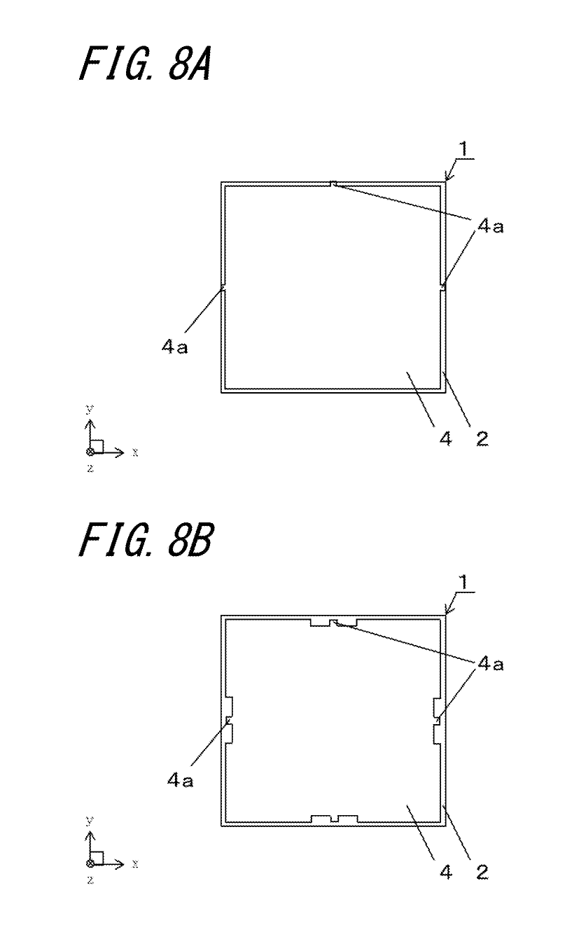

An image sensor mounting board 1 and an imaging device 21 according to a fourth embodiment of the present invention will now be described with reference to FIGS. 7A to 8B. The image sensor mounting board 1 and the imaging device 21 according to the present embodiment differ from the image sensor mounting board 1 and the imaging device 21 according to the first embodiment in that the protrusions 4a are formed on the outer edge of the inorganic substrate 4. Although the imaging device 21 according to the present embodiment includes the image sensor mounting board 1, an image sensor 10, and a lens holder 19, the lens holder 19 is not shown in FIGS. 7A and 7B.

In the present embodiment shown in FIGS. 7A and 7B, the protrusions 4a are formed on the outer edge of the inorganic substrate 4. This structure allows each protrusion 4a to serve as a support for the inorganic substrate 4 to reduce stress from, for example, warping of the inorganic substrate 4 when, for example, the inorganic substrate 4 receive stress from being dropped. The inorganic substrate 4 may be prevented from having breaks or cracks. This may also reduce deformation of the inorganic substrate 4, and allows the image sensor 10 mounted on the upper surface of the inorganic substrate 4 to remain aligned parallel to the lens holder 19 more accurately.

Each protrusion 4a may protrude outwardly from the outer edge of the inorganic substrate 4 as in the example shown in FIG. 8A. The inorganic substrate 4 may have cutouts on its outer edge as in the example shown in FIG. 8B, and the protrusion 4a may be formed inside each cutout. The protrusion 4a protruding outwardly from the outer edge of the inorganic substrate 4 as in the example shown in FIG. 8A may be more easily formed on the inorganic substrate 4. When multiple substrates 4 are formed adjacent to one another, the protrusions 4a may connect and hold the adjacent substrates 4. The protrusions 4a connecting the adjacent substrates 4 may simplify the process of splitting multiple adjacent substrates 4 from one another. When the outer edge of the inorganic substrate 4 has cutouts each containing the protrusion 4a as in the example shown in FIG. 8B, the size of the inorganic substrate 4 may be minimized. This prevents the outer edge of the inorganic substrate 4 from extending outwardly from the outer edge of the wiring board 2 as viewed from above when the inorganic substrate 4 is misaligned due to an error in the mounting process. The imaging device 21 can thus be downsized.

Three or more protrusions 4a as in the examples shown in FIGS. 8A and 8B allow the inorganic substrate 4 and the wiring board 2 to remain aligned parallel to each other more accurately and easily.

The protrusion 4a may have a thickness smaller than the thickness of the inorganic substrate 4 in a cross-sectional view as in the example shown in FIG. 7B. When the thickness of the protrusion 4a is smaller than the thickness of the other part of the inorganic substrate 4, the protrusion 4a can easily bend upward in a cross-sectional view. When the protrusions 4a are formed on the perimeter as in the example shown in FIG. 8A and multiple substrates 4 are connected and fixed using the protrusions 4a as described above, the substrates 4 can be split from one another more easily in the splitting process.

The protrusion 4a in the example shown in FIG. 7B may be formed by, for example, pressing the lower surface of the inorganic substrate 4 to be the protrusion 4a using, for example, a mold to form the protrusion 4a protruding from the inorganic substrate 4.

### REFERENCE SIGNS LIST

1 image sensor mounting board
2 wiring board
3 image sensor connection pad
4 inorganic substrate
4a protrusion
10 image sensor
11 image sensor mount
12 lid
13 connection
14 bonding member
15 bond
16 adhesive
19 lens holder
21 imaging device

1. An image sensor mounting board, comprising:
an inorganic substrate including an image sensor mount in a central area of an upper surface of the inorganic substrate, and a protrusion protruding upward in a peripheral area surrounding the image sensor mount, the image sensor mount being an area in which an image sensor is mountable;
a wiring board that is a frame arranged on an upper surface of the inorganic substrate to surround the image sensor mount and have a lower surface partially in contact with the protrusion, the wiring board including a lens mount on an upper surface thereof; and
a bond located between the inorganic substrate and the wiring board.

2. The image sensor mounting board according to claim 1, wherein
the inorganic substrate includes a plurality of the protrusions on the upper surface, and the protrusions are located at least on both sides of the image sensor mount.

3. The image sensor mounting board according to claim 2, wherein
the protrusions are located at horizontally symmetric positions on the image sensor mount.

4. The image sensor mounting board according to claim 1, wherein
the inorganic substrate has a recess in a lower surface thereof at a position overlapping the protrusion.

5. The image sensor mounting board according to claim 1, wherein
the protrusion is located on an outer edge of the inorganic substrate.

6. An imaging device, comprising:
the image sensor mounting board according to claim 1;
an image sensor mounted on the image sensor mount included in the inorganic substrate in the image sensor mounting board; and
a lens holder fixed on the lens mount included in the wiring board.
